(19) United States
(12) Patent Application Publication
(10) Pub. No.: US 2003/0183902 A1
(43) Pub. Date: Oct. 2, 2003

(54) Integrated circuit schematic for current switching of a constant current source

(76) Inventor: Axel Hulsmann, Freiburg (DE)

Correspondence Address: SUTHERLAND ASBILL & BRENNAN LLP, 999 PEACHTREE STREET, N.E., ATLANTA, GA, 30309, US

(21) Appl. No.: 10/388,192

(22) Filed: Mar. 12, 2003

(30) Foreign Application Priority Data
Mar. 12, 2002 (DE) 10210761.0

(51) Int. Cl. H01L 29/00

(52) U.S. Cl. 257/531

(57) ABSTRACT

The instant invention relates to an integrated circuit schematic (20) for switching current of a constant current source, wherein an emitter (23) of one switching transistor (21) and an emitter (24) of another switching transistor (22) are coupled to each other at a connection point (25). An integrated high quality coil (30) is coupled between the connection point (25) and the constant current source. The integrated coil (30) counteracts current change at the time of switchover, thereby improving the switching behavior of the integrated circuit schematic (20).

The instant invention relates to an integrated circuit schematic for switching the current of a constant current source, an emitter of one switching transistor and an emitter of another switching transistor being coupled to each other at a connection point.

Integrated circuit schematic of this kind are employed in ECL (emitter coupled logic) circuit engineering. ECL circuit engineering provides integrated circuits having quick switching times. In an integrated circuit schematic in which the emitters of two switching transistors are coupled to each other the current of the constant current source is not switched on and off. Instead, it is merely switched over from one to the other of the two transistors. Furthermore, suitable selection of a logic level voltage prevents the switching transistors from getting into saturation. Conventional ECL circuit schematics have a small output voltage range in the order of a few 100 mV. Yet output voltage ranges of several volts are required to operate driver circuits having a differential structure, such as for lasers or modulators. In this case the maximum operating frequency is limited above all by the discharge time of the charge carriers in the collectors of the switching transistors.

It is, therefore, an object of the invention to indicate an improved integrated circuit schematic of the kind defined initially, offering higher switching frequencies and optimized switching behavior.

This object is met, in accordance with the invention, in an integrated circuit schematic as recited in the preamble of claim 1, by having an integrated high quality coil coupled between the connection point and the constant current source.

In comparison with conventional integrated circuit schematics, the provision of the integrated coil of high quality has the effect that the integrated coil, connected between the emitters of the switching transistors and the constant current source, counteracts any change in current at the time of switchover. In this manner the steepness of the switching flanks is increased upon switching of the current from the constant current source. Moreover, higher switching frequencies are allowed. A coil of which the high figure of merit is high disposes of little internal resistance and has but small or almost no stray capacitances at all.

In a preferred embodiment of the invention, a reduction of stray capacitances is achieved in that the integrated coil is implemented by air bridge technology.

In a convenient further development of the invention, the integrated circuit schematic may be implemented by III/V semiconductor technology. In view of the fact that III/V semiconductor substrates for integrated circuits are semi-insulating the use of these semiconductor materials causes only very small stray capacitances, especially in comparison with silicon substrates.

According to a preferred modification of the invention the circuit schematic is implemented by semiconductor technology on the basis of silicon as this permits application of the widespread and sophisticated Si semiconductor technology. Thick SiO₂ layers, for example, or another dielectric may be positioned between the integrated coil and the Si substrate.

In preferred further developments of the invention, both the one switching transistor and the other switching transistor may be embodied by a bipolar transistor, especially a hetero-bipolar transistor or a field effect transistor (FET), in particular a high electron mobility transistor (HEMT). In principle, the improved switching behavior of the integrated circuit schematic is obtained irrespective of the type of switching transistor so that the choice of a particular type of switching transistor permits to adapt the integrated circuit schematic specifically to different semiconductor technologies or applications.

The invention will be described further, by way of example, with reference to the accompanying drawings, in which:

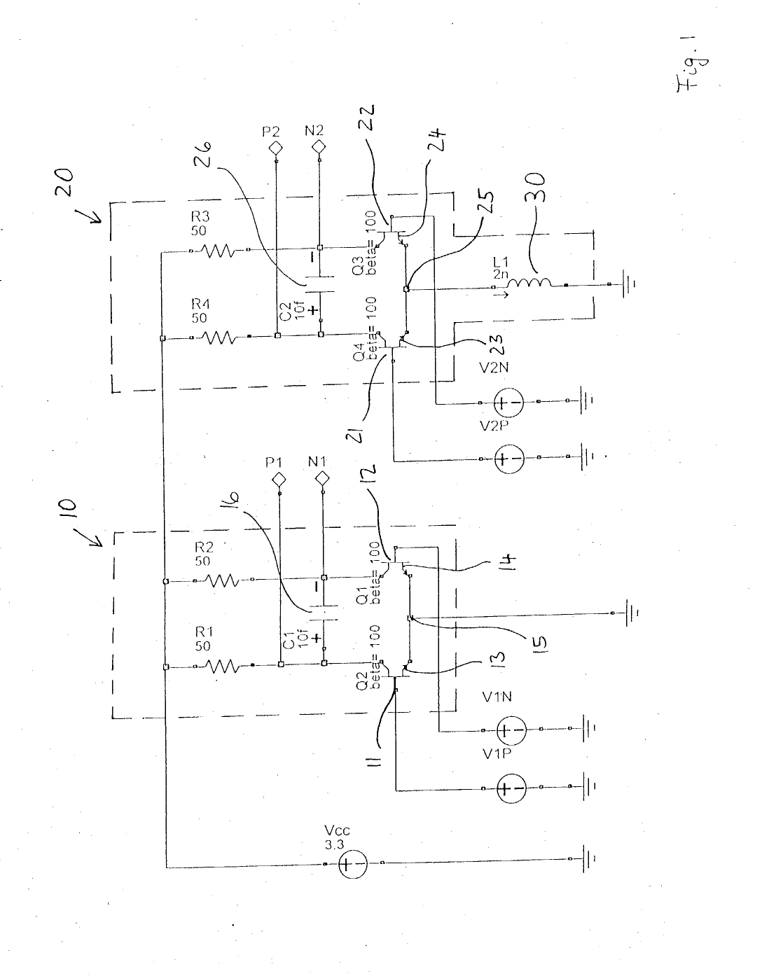

FIG. 1 shows circuit schematics of an ECL gate or differential driver with and without an integrated coil;

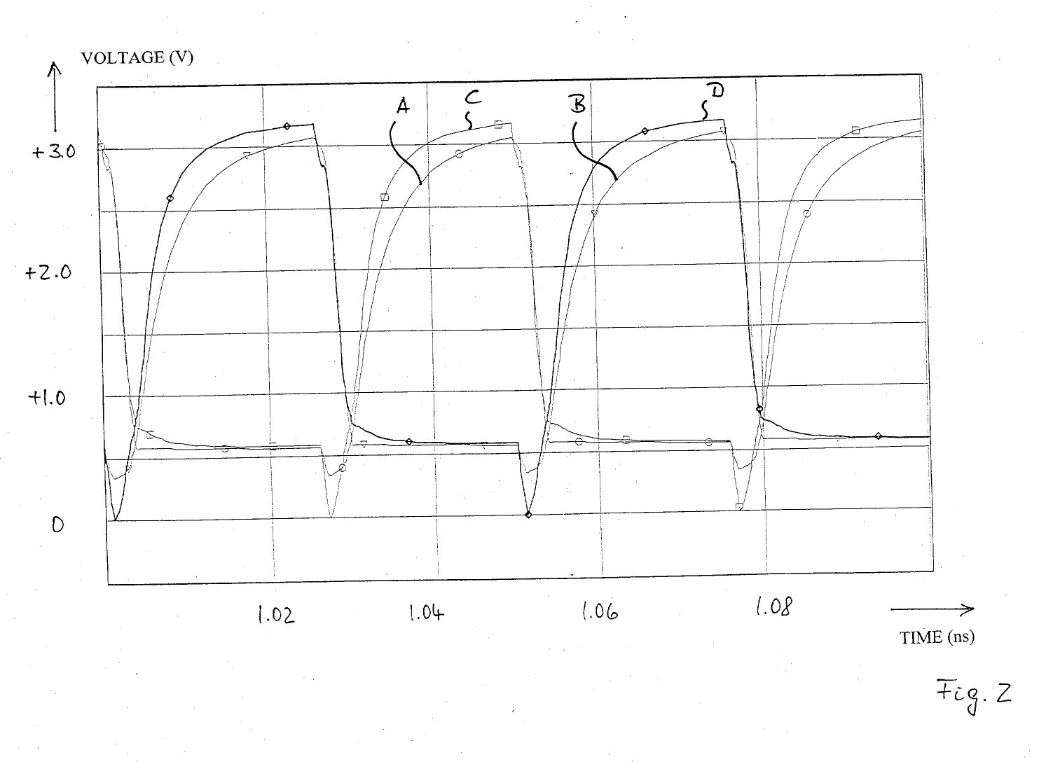

FIG. 2 is a graph illustrating a simulation of the switching behavior of the circuit schematics shown in FIG. 1.

FIG. 1 illustrates two circuit schematics 10, 20 comprising switching transistors 11, 12 and 21, 22, respectively. In both circuit schematics 10, 20 the emitters 13, 14 and 23, 24, respectively, of the switching transistors 11, 12, and 21, 22, respectively, are coupled to a connection point 15 and 25, respectively. Optionally, a capacitor 16 and 26, respectively, is coupled between differential outputs P1, N1 and P2, N2, respectively. The capacitor 16 and 26, respectively, likewise may be realized by parasitic effects in leads. The switching transistors 11, 12 and 21, 22, respectively, each serve to switch a current source. Alternatively, the connection point 15 and 25, respectively, in FIG. 1 is connected to ground instead of the current source to be switched.

Other than with the integrated circuit schematic 10, the integrated circuit schematic 20 comprises an integrated coil 30 which is coupled between the connection point 25 and ground (i.e. between the connection point 25 and the current source). The coil 30 is a suitably dimensioned integrated coil of high quality, in other words a coil having a low internal resistance and small stray capacitances or almost none.

It is easy to integrate the coil 30, especially so in connection with integrated circuit schematics including hetero-bipolar transistors or HEMTs on the basis of InP or GaAs. These kinds of III/V semiconductor substrates for integrated circuit schematics are semi-insulating and, therefore, cause extremely small stray capacitances compared to Si substrates which are either n-conductive or p-conductive. The circuit schematic 20 may be realized in practice on the basis of the widespread Si semiconductor technology. When the integrated coil is thus embodied thick SiO₂ layers or another dielectric may be utilized between the coil and the Si substrate.

Further reduction of stray capacitances is achieved, with the integrated coil 30, by applying an air bridge technique to produce the coil.

A comparison between the switching behavior over time of the integrated circuit schematics 10 and 20 is illustrated in FIG. 2. Curves A and B represent the switching behavior of the integrated circuit schematic 10 at outputs P1 and N1, respectively. The switching behavior of the integrated circuit schematic 20 at outputs P2 and N2 is illustrated by curves C and D, respectively.

The switching curves A, B, C, and D in FIG. 2 are based on simulated model calculations. Hetero-bipolar transistors were taken as the basis, having a forward transition time of 0.26 ps, a collector capacitance of 20 fF, and a emitter-base capacitance of 220 fF. As may be taken from FIG. 2, the steepness of the flank in the area of a positive switching flank is much greater for the integrated circuit schematic 20 (cf. curves C and D). In the area of negative switching flanks, the behavior is the same over wide ranges, both for the integrated circuit schematic 10 and the integrated circuit schematic 20. Therefore, when using the integrated circuit schematic 20 in differential laser or modulator driver circuits or ECL gates, in general, an improved visual diagram is obtained for the integrated circuits.

The improved switching behavior of the integrated circuit schematic 20 is obtained in connection with hetero-bipolar transistors as well as field effect transistors. This offers users the possibility of selecting the kind of switching transistor 21, 22 best suited for a particular purpose.

The features of the invention disclosed in the specification above, in the claims and drawing may be essential to practicing the invention in its various embodiments, both individually and in any combination.

What is claimed is:

1. An integrated circuit schematic (20) for switching current of a constant current source, an emitter (23) of one switching transistor (21) and an emitter (24) of another switching transistor (22) being coupled to each other at a connection point (25), characterized in that an integrated high quality coil (30) is coupled between the connection point (25) and the constant current source.

2. The integrated circuit schematic (20) as claimed in claim 1, characterized in that the integrated coil (30) is implemented by air bridge technology.

3. The integrated circuit schematic (20) as claimed in claim 1, characterized in that the circuit schematic (20) is implemented by III/V semiconductor technology.

4. The integrated circuit schematic (20) as claimed in claim 1, characterized in that the circuit schematic (20) is implemented by semiconductor technology based on silicon.

5. The integrated circuit schematic (20) as claimed in claim 1, characterized in that the switching transistor (21) and the other switching transistor (22) each are a bipolar transistor.

6. The integrated circuit schematic (20) as claimed in claim 1, characterized in that the switching transistor (21) and the other switching transistor (22) each are a field effect transistor.
